(19) United States
(12) Patent Application Publication
(10) Pub. No.: US 2005/0104158 A1
(43) Pub. Date: May 19, 2005

(54) COMPACT, HIGH Q INDUCTOR FOR INTEGRATED CIRCUIT

(75) Inventors: Jishnu Bhattacharjee, San Jose, CA (US); Madabusi Govindarajan, Sunnyvale, CA (US); Debanjan Mukherjee, San Jose, CA (US); Abhijit Phanse, Sunnyvale, CA (US); Prashant Choudhary, San Jose, CA (US)

Correspondence Address: Theodore P. Lopez;MacPHERSON KWOK CHEN & HEID LLP, Suite 226, 1762 Technology Drive, San Jose, CA, 95110, US

(73) Assignee: Scintera Networks, Inc.

(21) Appl. No.: 10/718,501

(22) Filed: Nov. 19, 2003

(51) Int. Cl. H01L 29/00

(52) U.S. Cl. 257/531

(57) ABSTRACT

An inductor for an integrated circuit made of a plurality of stacked, electrically coupled, metal layers. Each metal layer includes an inductor formed of a spiral pattern, which except for the top and bottom inductors, are electrically coupled to the spiral inductor formed on the metal layer above and below with an electrical path or via formed between each metal layer. The top and bottom inductors are electrically coupled to the inductor directly below and above, respectively.

### BACKGROUND

1. Field of the Invention

The present invention pertains generally to integrated circuits, and more particularly, to integrated circuits having inductors of high quality.

2. Related Art

Inductors are fabricated as part of integrated circuits (IC) to increase the functionality of the IC and to reduce its cost and size. Generally, inductors are formed as a spiral structure which lies in a plane in a layer of the IC. Most IC applications require a planar inductor with a high Q (quality factor). The Q of an inductor is proportional to the magnetic energy stored in the inductor divided by the energy dissipated in the inductor in one oscillation cycle. The amount of magnetic energy stored in an inductor is directly proportional to the inductance of the inductor. The amount of energy dissipated in the inductor depends on resistive elements associated with the inductor.

Unfortunately, forming a spiral planar inductor on an IC does not necessarily result in a high Q device. For instance, an increase in the power dissipated in the resistive elements associated with the inductor adversely affects the Q of the inductor. For example, a typical circuit implanted in an IC has resistive elements, including a resistive substrate. Highly resistive substrates provide isolation of active devices and lower substrate eddy currents, however, silicon substrates are conductive. A voltage between the inductor and the substrate ground creates an electric field across an insulation layer and the resistive substrate. If the voltage varies, the resulting changing electric field will cause current to flow through the resistive substrate. The current flow through the resistive substrate dissipates power. The losses due to the dissipated power reduce the Q of the inductor.

Moreover, a spiral inductor formed in a single plane covers a relatively large area of the IC. Since the availability of area on the IC is at a premium, the cost of the IC increases as the size of the spiral inductor increases. Also, any increase in size of the IC without using a stacked inductor can have a lower yield.

What is needed is an inductor structure that provides a high Q, which occupies a reduced amount of area on the IC.

### SUMMARY

The present invention provides an inductor made of a plurality of stacked, electrically coupled, metal layers. In accordance with the present invention, each metal layer includes an inductor formed of a spiral pattern. Each spiral inductor is electrically coupled to the spiral inductor formed on each adjacent metal layer above and below with an electrical path or via formed between each metal layer.

As described in greater detail below, each spiral inductor is formed as if an imaginary observer rotates in a spiral direction until the observer has rotated 360° forming a single turn. After a single turn, the observer is on the same radius line as where the observer began, except at a different distance on the radius. The observer continues on the spiral path until the desired number of turns is completed.

Each spiral inductor is formed of multiple straight segments, which cause each spiral inductor to resemble a polygon. As the number of segments is increased, the efficiency of the inductor approaches that of a circular inductor.

In one aspect of the invention a method is provided for forming a first spiral inductor having a first end at an outer radius of the spiral and a second end at an inner radius of the spiral on a first layer of a substrate. The method also includes forming a second spiral inductor having a first end at an inner radius of the spiral and a second end at an outer radius of the spiral on a second layer of the substrate and electrically coupling the first end of the second spiral inductor to the second end of the first spiral inductor through a via disposed between the first and second layers.

In yet another aspect of the invention a stacked inductor is provided which includes a first inductor formed in a spiral having at least two substantially complete turns and at least five segments and having a first end positioned at an outer radius of the spiral and a second end positioned at an inner radius of the spiral; and a second inductor formed in a spiral having at least two complete turns and at least five segments and having a first end positioned at an inner radius of the spiral and a second end positioned at an outer radius of the spiral. The second end of the first inductor is electrically coupled to the first end of the second inductor.

The stacked inductor structure of the present invention provides the smallest area for a given inductance value. This objective is accomplished since the stacked inductor provides a Q proportional to the square of the number Z of metal layers (i.e. Q proportional to Z²). For example, if each layer has a unit inductance Lᵤ and unit resistance Rᵤ, then an inductor in Z layers has approximately:
L_{eff=L}ᵤ*Z²
R_{eff=R}ᵤ*Z.

Thus, the Q (=ωL/R) increases by a factor of Z. Advantageously, as a result of this relationship the total area A of the IC consumed by the stacked inductor is 1/Z² of the area Ac of the area consumed by a single plane inductor (i.e. A=(1/Z²)Ac). Although the stacked inductor occupies less area on the IC then the single plane inductor, it can provide a comparable high Q and the highest self-resonance frequency. This significantly reduces the cost and increases the performance of the IC.

These and other features of the present invention will be more readily apparent from the detailed description of the embodiments set forth below taken in conjunction with the accompanying drawings.

### BRIEF DESCRIPTION OF THE FIGURES

FIGS. 1A, 1B, 1C, 1D, 1E, 1F, 1G and 1H are simplified cross-sectional views illustrating a method for fabricating a spiral inductor according to an embodiment of the present invention;

FIG. 2 is an equivalent circuit depicting of the structure created as shown in FIGS. 1A-1H;

FIG. 3A is a simplified perspective view of a stacked spiral inductor in accordance with an embodiment of the present invention;

FIG. 3B is a simplified cross-sectional view of the stacked inductor of FIG. 3A; and

FIG. 4 is a simplified illustration of spiral inductors positioned on separate layers formed with alternating rotational formations in accordance with an embodiment of the present invention.

A detailed description of embodiments according to the present invention will be given below with reference to accompanying drawings

### DETAILED DESCRIPTION

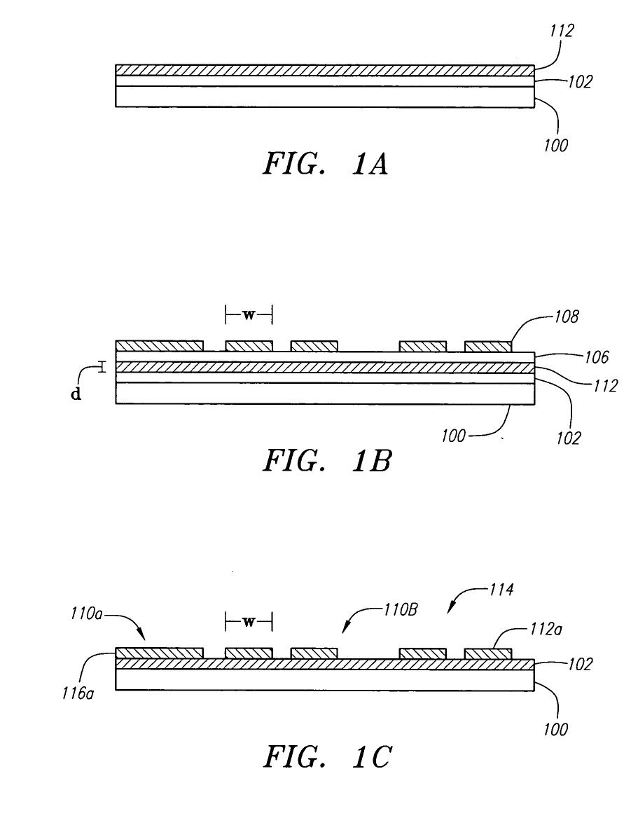

FIGS. 1A to 1H are simplified cross-sectional views illustrating a method for fabricating a stacked inductor in accordance with an embodiment of the present invention.

As shown in FIG. 1A, a silicon substrate 100 is provided. In one embodiment, silicon substrate 100 may include CMOS active and passive elements, such as those generally well known in the art.

A first dielectric layer 102, such as a silicon dioxide (for example, tetraethylorthosilicate (TEOS)/borophosphosilicate glass (BPSG)) is formed on substrate 100. A first metal layer 112 is deposited on first dielectric layer 102. First metal layer 112 (and all subsequently deposited metal layers) can be formed to any appropriate thickness d and can be made with variable width w (FIG. 1B). In one embodiment, to reduce resistance, metal layer 112 can have a thickness d of at least 1 μM. In other embodiments, thickness d can range from about 2 μm to about 5 μm. First metal layer 112 can be any suitably conductive material, such as copper (Cu), Aluminum (Al), alloys of these metals, and the like.

As shown in FIG. 1B, a second dielectric layer 106, such as a silicon oxide layer, a silicon nitride layer, a silicon oxide/silicon nitride layer, or a SiO₂/SOG(spin-on-glass)/SiO₂ layer, is formed on metal layer 112. A first photoresist layer is formed on the second dielectric layer 106, to form a first photoresist pattern 108. First photoresist pattern 108 forms a spiral pattern, for example, by a photolithography process, of concentric multiple turns. Each turn of the spiral includes multiple segments, which cause each turn to resemble a polygon.

The exposed second dielectric layer 106 is etched (for example, dry etched) using the first photoresist pattern 108 as an etching mask, thus forming a spiral pattern of dielectric 106 on metal layer 112.

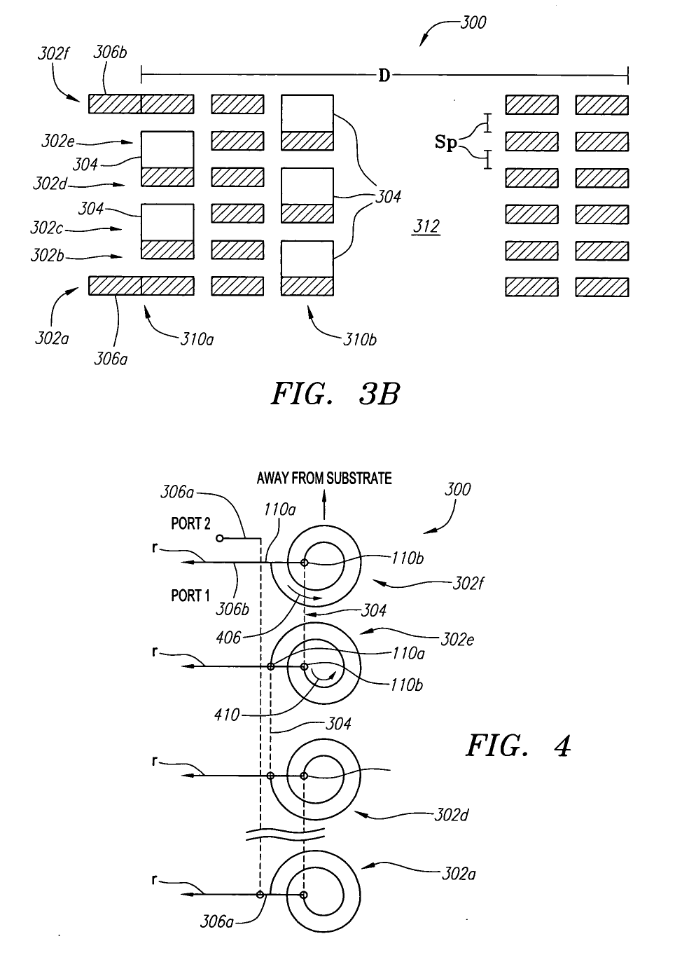

As shown in FIG. 1C, metal layer 112 is dry etched using photoresist pattern 108 and patterned dielectric 106, to form first spiral inductor 112a having the segmented spiral shape. The width w of each segment of the spiral, thus formed, can be varied as required by a particular application. In one embodiment, the width w can range from about 0.5 μm to about 2.5 μm. However, it should be understood that the minimum metal width is governed by the semiconductor process. For an inductor, the width can vary based on inductance value, quality factor and maximum allowable area. First spiral inductor 112a, commences at an outer distance 110a on a given radius line r (hereinafter “outer radius”), and in one embodiment, terminates at an inner distance 110b on the same radius line r (hereinafter “inner radius”) (see e.g., FIG. 4).

First metal layer 112 can include a lead 116a, which extends from an end portion of first spiral inductor 112a at outer radius 110a to the edge of the IC. Lead 116a can be formed using the same photoresist pattern 108 as used to form first spiral inductor 112a.

As shown in FIG. 1D, the formation of the next metal layer begins by forming a third dielectric layer 118 on the resulting structure having first spiral inductor 112a.

A second photoresist layer is formed on third dielectric layer 118, to form a second photoresist pattern 120. A via 122 is formed by etching third dielectric layer 118 using the second photoresist pattern 120 as an etching mask, to expose an end portion at an inner radius of first spiral inductor 112a. The remaining photoresist pattern 120 is then removed.

As shown in FIG. 1E, a second metal layer 124 is deposited on the resulting structure. A fourth dielectric layer 126, such as a silicon oxide layer, a silicon nitride layer or a silicon oxide/silicon nitride layer is formed on second metal layer 124.

After forming a photoresist layer on the fourth dielectric layer 126, a third photoresist pattern 128 is formed to once again create the segmented spiral pattern. The exposed fourth dielectric layer 126 is dry etched using the third photoresist pattern 128 as an etching mask, thus forming a spiral dielectric pattern on metal layer 124. The spiral dielectric pattern is a shadow of first spiral inductor 112a.

As shown in FIG. 1F, metal layer 124 is dry etched using fourth dielectric pattern 126, to form second spiral inductor 124a having the aforementioned segmented spiral shape.

Second spiral inductor 124a is formed in contact with first spiral inductor 112a through via 122 formed at inner radius 110b of the first and second spiral inductors (112a and 124a). Second spiral inductor 124a is coupled to first spiral inductor 112a at inner radius 110b, therefore, it follows that second spiral inductor 124a can be coupled to the next formed spiral inductor at outer radius 110a. Referring again to FIG. 1F, the formation of the next metal layer begins by forming a fifth dielectric layer 130 on the resulting structure having second spiral inductor 124a.

A fourth photoresist layer is formed on the fifth dielectric layer 130, to form a fourth photoresist pattern 132. Via 134 is formed by etching fifth dielectric layer 130 using the fourth photoresist pattern 132 as an etching mask, to expose an end portion at outer radius 110a of second spiral inductor 124a. The remaining photoresist pattern 132 is then removed.

As shown in FIG. 1G, a third metal layer 136 is deposited on the resulting structure. A sixth dielectric layer 138 is formed on third metal layer 136.

After forming a photoresist layer on sixth dielectric layer 138, a fifth photoresist pattern 140 is formed again to create the segmented spiral commencing at outer radius 110a and terminating at inner radius 110b. The exposed sixth dielectric layer 138 is dry etched using fifth photoresist pattern 140 as an etching mask, thus forming a spiral dielectric pattern on third metal layer 136. The spiral dielectric pattern is a shadow of second spiral inductor 124a.

As shown in FIG. 1H, third metal layer 136 is dry etched using sixth dielectric pattern 138, to form third spiral inductor 136a having the segmented spiral shape. Third spiral inductor 136a is formed in contact with second spiral inductor 124a through via 134 at outer radius 110a of the second and third spiral inductors (124a and 136a).

In the exemplary embodiment just described, stacked inductor 150 is shown to include three spiral inductors 112a, 124a and 136a. Thus, to complete the 3 layer stacked inductor 150, third spiral inductor 136a is formed with lead 116b formed at an outer radius 110a to the edge of the IC.

FIG. 1H, shows a passivation layer 142 as a dielectric layer protecting stacked inductor 150, which can be formed once completion of the desired number of spiral inductors are fabricated.

Although the exemplary embodiment just described shows a process for forming a stacked inductor 150 having only three spiral inductors 112a, 124a, and 136a, it should be understood by one of ordinary skill in the art that the same process can be extrapolated to form a stacked inductor having any number of spiral inductors that may be of use for a particular application.

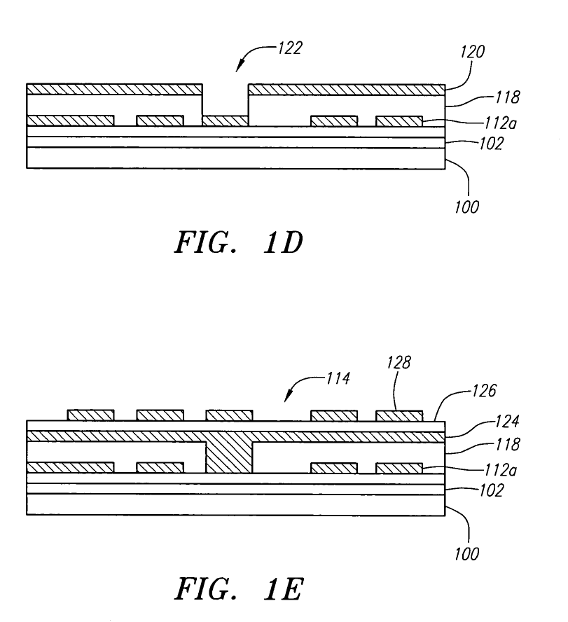

FIG. 2 is an equivalent circuit 200 of IC structure 152 in accordance with an embodiment of the present invention. Note that equivalent circuit 200 is a lumped approximation of IC structure 152, which is actually a distributed structure. As shown in the figure, L represents the ideal inductor that is clouded by the parasitic DC resistance R_{dc}, and the AC resistance R_{ac}, including skin and proximity effects. The inductance is also clouded by the parasitic capacitances to ground C₁, which is the capacitance lumped into Port 1 and likewise with C₂, which is the capacitance lumped into Port 2.

The ground shown in the figure is to be viewed as a return path for the current flowing through inductor L, and is itself distributed, including the ground conductor of the circuitry where inductor L is embedded, and in addition, the semiconductor substrate, ground shields, and power supply lines as appropriate.

Capacitances C₁ and C₂ represent the electrostatic linkage between the turns of inductor L and the ground, and the inter-coil electrostatic coupling. Asymmetry exists between capacitances C₁ and C₂ since Port 2 is closer to the substrate than Port 1.

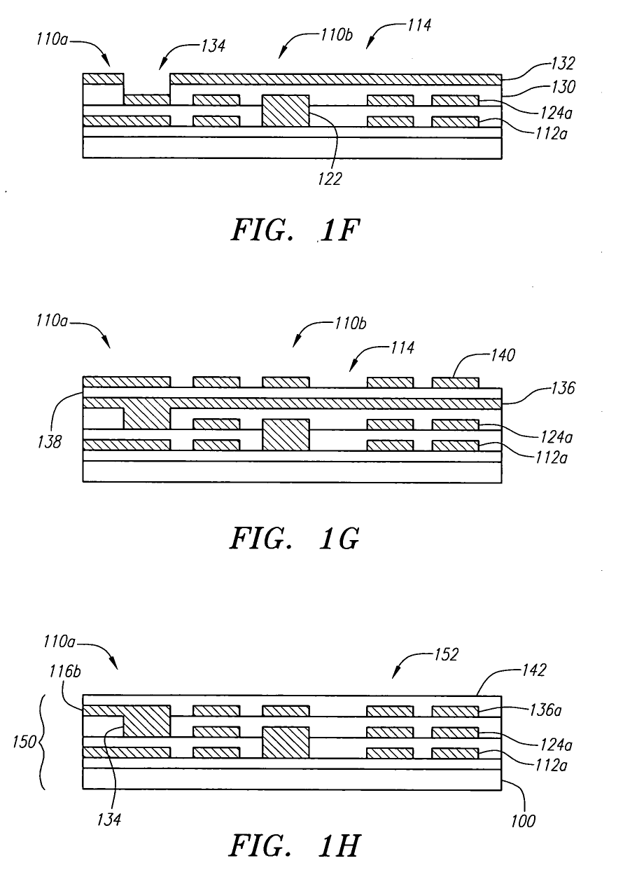

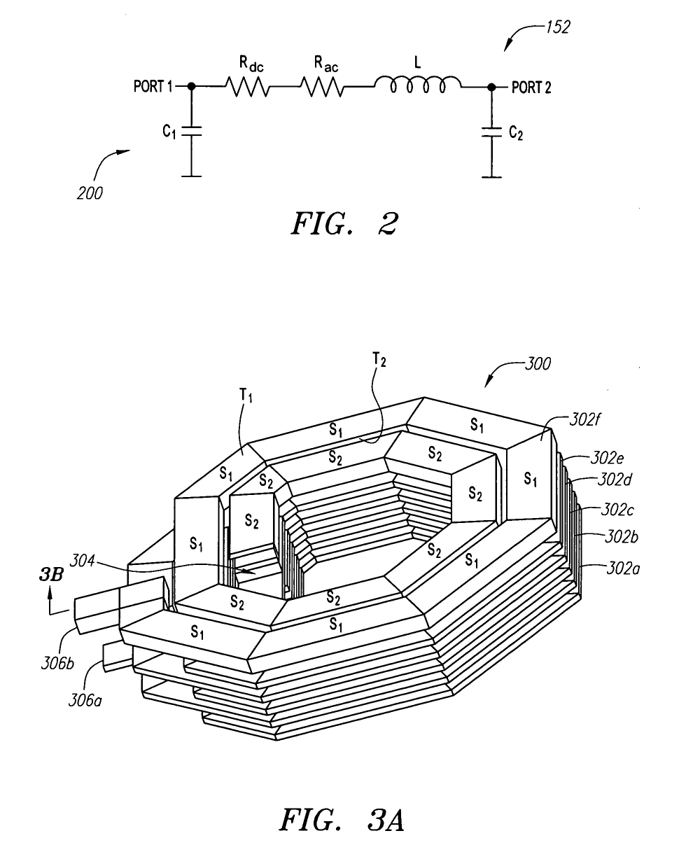

FIG. 3A is a simplified perspective view of a stacked spiral inductor 300 including multiple metal layers in accordance with an embodiment of the present invention. Stacked inductor 300 can have any number of metal layers (m), for example, in one embodiment, stacked inductor 300 includes m=6 metal layers each having a spiral inductor 302a-302f formed thereon. The number of layers (m) provides a mutual inductance L which is greater than the individual inductance provided by each spiral inductor.

Each spiral inductor 302a-302f is formed of a spiral pattern having multiple turns T each formed having multiple segments per turn S_{T} that when formed together resembles a structure of concentric multi-sided shapes. In one embodiment, leads 306a and 306b are provided at the beginning portion of spiral inductor 302a and at an end portion of spiral inductor 302f, respectively, for electrically contacting and grounding stacked inductor 300.

The spiral inductor configuration of a predetermined number of turns T can be varied based on a specific application. In one embodiment, the number of turns T can range from 1 to 4 turns, for example, 2 turns.

As the number of turns T increases, the number of segments per turn S_{T} may also increase. The increased number of segments per turn S_{T} causes the performance of the spiral inductor to approach that which would be achieved with a perfectly circular inductor. In one embodiment, the number of segments per turn S_{T} can range from between 4 and 20 segments per turn. Preferably, the number of segments per turn S_{T} is 5 or greater.

To achieve near-perfect coupling the spacing between spiral inductors 302a-302f can be made much smaller than the diameter of the spirals. Although their is no fundamental limit or constraint on the spacing or diameter of the spiral inductors, as shown in FIG. 3B, in one embodiment, the spacing sp between each spiral inductor 302a-302f may range from between about 0.5 μm and about 2.5 μm. The diameter D to the outer turn of each spiral inductor 302a-302f can range from between about 10 μm and about 50 μm.

Referring again to FIG. 3B, once formed, spiral inductors 302a-302f define a central hollow center 312. The outer turn associated with the each spiral inductor occupies a larger area within its perimeter, which is available to handle an increase in flux. However, as the turns of the spiral begin to acquire a smaller radius, the area through which the flux can pass grows increasingly smaller. Thus, central hollow center 312 is maintained with as much area as possible within the turns of spiral inductors 302a-302f to allow for the flux.

As shown in FIG. 3B, each spiral inductor 302a-302f is electrically coupled through an electrical pathway defined by vias 304 to the spiral inductor formed above and below. The positioning of vias 304 alternates from outer radius 310a to inner radius 310b for reasons explained below with regard to FIG. 4.

FIG. 4 is a simplified illustration of spiral inductors in accordance with an embodiment of the present invention. For example, first inductor 302f, shown as the inductor furthest away from the substrate, is formed as if having been rotated in a given direction, for example, in a counter-clockwise direction from an outer radius 110a to an inner radius 110b as indicated by arrow 406. This reference to rotation is indicated only to suggest how each spiral inductor is to be formed relative to each other spiral inductor with regard to the location of the electrical coupling of the spiral inductors.

Spiral inductor 302e is formed below first inductor 302f, as if having been rotated in an opposite direction to the given direction (arrow 406) above, in a clockwise direction from inner radius 110b to outer radius 110a as indicated by arrow 410. The rotational direction of spiral inductor 302e formed on the second layer is made to shadow the rotational direction of spiral inductor 302f on the first layer to follow the right hand rule convention.

The alternating outer radius to inner radius and inner radius to outer radius coupling configuration between spiral inductors 302e and 302f is extended to each of the other spiral inductors 302a-302d to form complete spiral inductor 300. (see also FIG. 3B)

By placing spiral inductors on a plurality of metal layers, the area of the IC consumed by each spiral inductor can be substantially reduced. Beneficially, this allows the final IC product to be made smaller, and therefore, with a greater economy of scale in manufacturing. This benefit is illustrated with the following example.

With reference to equation (1), an IC including, for example, six metal layers (n) each having electrically coupled spiral inductors can achieve 36 times the inductance (L) of a single spiral inductor having a given diameter with a given inductance.
L_{eff} α n₂L (1)

Thus, in this example, the area that would otherwise be consumed by a single layer inductor on the IC can be reduced by a factor of 36. Since the inductor in silicon CMOS technology is the dominant factor in the size of the IC chip, reducing the inductor to a size 1/36 of its former size, translates into almost a 1/36 reduction in chip size.

The small inductor radius provides the ability to reduce the total capacitance associated with the inductor relative to the substrate. This increases the self-resonant frequency of the IC and allows the IC to be used at higher frequencies. This particular advantage is amplified for communication technologies in the gigabit range, for example, as the frequencies for digital transmission move into the 10 gigabit to 40 gigabit range.

In an exemplary embodiment, a six layer stacked inductor 300 (FIG. 3A) configured with two turns T₁ and T₂ each having eight segments S₁ and S₂ so as to generally form an octagonal shaped inductor when viewed from the plan view has been shown to be capable of providing approximately 6.3 μH of inductance while occupying an area of approximately 30 μm by 30 μm.

In one embodiment, the dimensions of spiral inductors and the number of layers required can be determined through an iterative design process to provide a desired inductance for a given set of input parameters.

Having thus described embodiments of the present invention, persons skilled in the art will recognize that changes may be made in form and detail without departing from the spirit and scope of the invention. Thus the invention is limited only by the following claims.

1-5. (canceled)

6. A stacked inductor comprising:
a semiconductor substrate;
a plurality of conductive layers formed on the substrate, the plurality of conductive layers being arranged from a first conductive layer closest to the, substrate to a last conductive layer furthest from the substrate; and
a plurality of conductive spirals corresponding to the plurality of conductive layers such that a first spiral is formed in the corresponding first conductive layer, a second spiral is formed in the corresponding second conductive layer, and so on, wherein each spiral includes at least two concentric turns coiled from a first end at an outer radius of the spiral to a second end at an inner radius of the spiral; wherein the first end of the first spiral forms a first port for the inductor, a second end of the first spiral couples through a first via to the second end of the second spiral, the first end of the second spiral couples though a second via to the first end of the third spiral, and so on such that the second end of the next-to-last spiral couples through a last via to the second end of the last spiral, the first end of the last spiral forming a second port for the inductor.

7. The stacked inductor of claim 6, wherein each turn of each spiral comprises five or more linear segments.

8. The stacked inductor of claim 6, wherein each spiral has a thickness of between 1 an to 4 μm.

9. The stacked inductor of claim 6, wherein each spiral comprises a conductive metal taken from the group consisting of Cu, Al and alloys thereof.

10. The stacked inductor of claim 7, wherein the number of linear segments equals eight.

11. The stacked inductor of claim 6, wherein the first port is coupled to a power.

12-16. (canceled)
